(19) United States
(12) Patent Application Publication
(10) Pub. No.: US 2023/0409094 A1
(43) Pub. Date: Dec. 21, 2023

(54) SYSTEMS AND METHODS FOR CONTROLLING AIR MOVER PERFORMANCE BASED ON ALTITUDE

(71) Applicant: Dell Products L.P., Round Rock, TX (US)

(72) Inventors: Shih-Huai CHO, New Taipei City (TW); Chun-Chin WEN, New Taipei City (TW)

(73) Assignee: Dell Products L.P., Round Rock, TX (US)

(21) Appl. No.: 17/840,804

(22) Filed: Jun. 15, 2022

(51) Int. Cl. G06F 1/20; H05K 7/20

(52) U.S. Cl. CPC G06F 1/20; H05K 7/20209; G06F 2200/201

(57) ABSTRACT

An information handling system may include an information handling resource, an air mover configured to drive air to cool the information handling resource, and a thermal control system for controlling the air mover and configured to, based on an altitude of the information handling system, regulate an air mover speed of the air mover.

### TECHNICAL FIELD

The present disclosure relates in general to information handling systems, and more particularly to providing air mover speed optimization based on altitude.

### BACKGROUND

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

As processors, graphics cards, random access memory (RAM) and other components in information handling systems have increased in clock speed and power consumption, the amount of heat produced by such components as a side-effect of normal operation has also increased. Often, the temperatures of these components need to be kept within a reasonable range to prevent overheating, instability, malfunction and damage leading to a shortened component lifespan. Accordingly, air movers (e.g., cooling fans and blowers) have often been used in information handling systems to cool information handling systems and their components.

Temperature control in an information handling system with air movers often involves use of a closed-loop feedback system that alters air mover speed in response to a sensed temperature in the information handling system. However, at higher altitudes, heat dissipation by way of air cooling may be smaller as compared with lower altitudes, due to lower air density found at higher altitudes.

### SUMMARY

In accordance with the teachings of the present disclosure, the disadvantages and problems associated with optimizing air mover speed in an information handling system may be substantially reduced or eliminated.

In accordance with embodiments of the present disclosure, an information handling system may include an information handling resource, an air mover configured to drive air to cool the information handling resource, and a thermal control system for controlling the air mover and configured to, based on an altitude of the information handling system, regulate an air mover speed of the air mover.

In accordance with these and other embodiments of the present disclosure, a method may include obtaining an indication of an altitude of an information handling system and based on an altitude of the information handling system, regulating an air mover speed of an air mover of the information handling system.

In accordance with these and other embodiments of the present disclosure, an article of manufacture may include a non-transitory computer-readable medium and computer-executable instructions carried on the computer-readable medium, the instructions readable by a processing device, the instructions, when read and executed, for causing the processing device to obtain an indication of an altitude of an information handling system and based on an altitude of the information handling system, regulate an air mover speed of an air mover of the information handling system.

Technical advantages of the present disclosure may be readily apparent to one skilled in the art from the figures, description and claims included herein. The objects and advantages of the embodiments will be realized and achieved at least by the elements, features, and combinations particularly pointed out in the claims.

It is to be understood that both the foregoing general description and the following detailed description are examples and explanatory and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 illustrates a block diagram of an example information handling system, in accordance with embodiments of the present disclosure; and

FIG. 2 illustrates a flow chart of an example method for air mover speed optimization based on altitude, in accordance with embodiments of the present disclosure.

### DETAILED DESCRIPTION

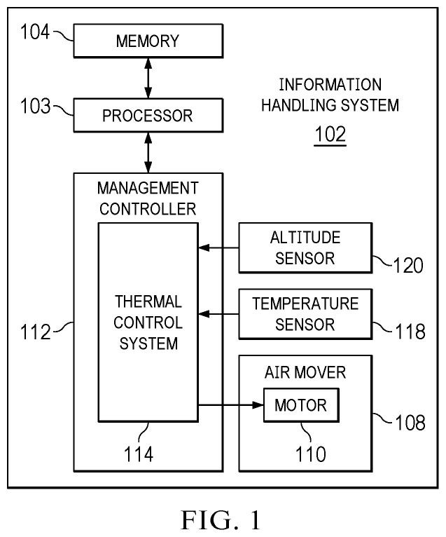

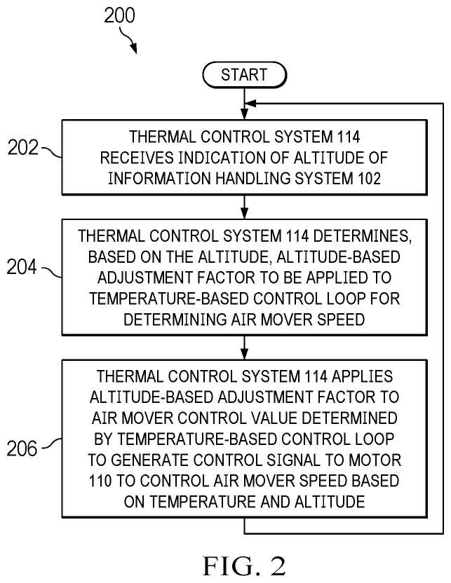

Preferred embodiments and their advantages are best understood by reference to FIGS. 1 and 2, wherein like numbers are used to indicate like and corresponding parts.

For the purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, an information handling system may be a personal computer, a PDA, a consumer electronic device, a network storage device, or any other suitable device and may vary in size, shape, performance, functionality, and price. The information handling system may include memory, one or more processing resources such as a central processing unit (CPU) or hardware or software control logic. Additional components of the information handling system may include one or more storage devices, one or more communications ports for communicating with external devices as well as various input and output (I/O) devices, such as a keyboard, a mouse, and a video display. The information handling system may also include one or more buses operable to transmit communication between the various hardware components.

For the purposes of this disclosure, computer-readable media may include any instrumentality or aggregation of instrumentalities that may retain data and/or instructions for a period of time. Computer-readable media may include, without limitation, storage media such as a direct access storage device (e.g., a hard disk drive or floppy disk), a sequential access storage device (e.g., a tape disk drive), compact disk, CD-ROM, DVD, random access memory (RAM), read-only memory (ROM), electrically erasable programmable read-only memory (EEPROM), and/or flash memory; as well as communications media such as wires, optical fibers, microwaves, radio waves, and other electromagnetic and/or optical carriers; and/or any combination of the foregoing.

For the purposes of this disclosure, information handling resources may broadly refer to any component system, device or apparatus of an information handling system, including without limitation processors, buses, memories, I/O devices and/or interfaces, storage resources, network interfaces, motherboards, integrated circuit packages, electro-mechanical devices (e.g., air movers), displays, and power supplies.

FIG. 1 illustrates a block diagram of an example information handling system 102, in accordance with embodiments of the present disclosure. In some embodiments, information handling system 102 may comprise a server chassis configured to house a plurality of servers or “blades.” In other embodiments, information handling system 102 may comprise a personal computer (e.g., a desktop computer, laptop computer, mobile computer, and/or notebook computer). In yet other embodiments, information handling system 102 may comprise a storage enclosure configured to house a plurality of physical disk drives and/or other computer-readable media for storing data. As shown in FIG. 1, information handling system 102 may comprise a processor 103, a memory 104, an air mover 108, a management controller 112, a temperature sensor 118, and an altitude sensor 120.

Processor 103 may comprise any system, device, or apparatus operable to interpret and/or execute program instructions and/or process data, and may include, without limitation a microprocessor, microcontroller, digital signal processor (DSP), application specific integrated circuit (ASIC), or any other digital or analog circuitry configured to interpret and/or execute program instructions and/or process data. In some embodiments, processor 103 may interpret and/or execute program instructions and/or process data stored in memory 104 and/or another component of information handling system 102.

Memory 104 may be communicatively coupled to processor 103 and may comprise any system, device, or apparatus operable to retain program instructions or data for a period of time. Memory 104 may comprise random access memory (RAM), electrically erasable programmable read-only memory (EEPROM), a PCMCIA card, flash memory, magnetic storage, opto-magnetic storage, or any suitable selection and/or array of volatile or non-volatile memory that retains data after power to information handling system 102 is turned off.

Air mover 108 may include any mechanical or electro-mechanical system, apparatus, or device operable to move air and/or other gases in order to cool information handling resources of information handling system 102. In some embodiments, air mover 108 may comprise a fan (e.g., a rotating arrangement of vanes or blades which act on the air). In other embodiments, air mover 108 may comprise a blower (e.g., a centrifugal fan that employs rotating impellers to accelerate air received at its intake and change the direction of the airflow). In these and other embodiments, rotating and other moving components of air mover 108 may be driven by a motor 110. The rotational speed of motor 110 may be controlled by an air mover control signal (e.g., a pulse-width modulation signal) communicated from thermal control system 114 of management controller 112. In operation, air mover 108 may cool information handling resources of information handling system 102 by drawing cool air into an enclosure housing the information handling resources from outside the chassis, expel warm air from inside the enclosure to the outside of such enclosure, and/or move air across one or more heat sinks (not explicitly shown) internal to the enclosure to cool one or more information handling resources.

Management controller 112 may comprise any system, device, or apparatus configured to facilitate management and/or control of information handling system 102 and/or one or more of its component information handling resources. Management controller 112 may be configured to issue commands and/or other signals to manage and/or control information handling system 102 and/or its information handling resources. Management controller 112 may comprise a microprocessor, microcontroller, DSP, ASIC, field programmable gate array (“FPGA”), EEPROM, or any combination thereof. Management controller 112 also may be configured to provide out-of-band management facilities for management of information handling system 102. Such management may be made by management controller 112 even if information handling system 102 is powered off or powered to a standby state. In certain embodiments, management controller 112 may include or may be an integral part of a baseboard management controller (BMC), a remote access controller (e.g., a Dell Remote Access Controller or Integrated Dell Remote Access Controller), or an enclosure controller. In other embodiments, management controller 112 may include or may be an integral part of a chassis management controller (CMC).

As shown in FIG. 1, management controller 112 may include a thermal control system 114. Thermal control system 114 may include any system, device, or apparatus configured to receive one or more signals indicative of one or more temperatures within information handling system 102 (e.g., one or more signals from one or more temperature sensors 118), further configured to receive one or more signals indicative of an altitude at which information handling system 102 is located (e.g., one or more signals from altitude sensor 120), and based on such signals, calculate an air mover driving signal (e.g., a pulse-width modulation signal) to maintain an appropriate level of cooling, increase cooling, or decrease cooling, as appropriate, and communicate such air mover driving signal to air mover 108. Thermal control for air mover 108 by thermal control system 114 may be performed in any suitable manner, for example, as described in U.S. Pat. No. 10,146,190 entitled “Systems and Methods for Providing Controller Response Stability in a Closed-Loop System.”

In addition, thermal control system 114 may also be configured to maintain acoustic limits and/or maintain acoustic preferences for sound generated by air mover 108, for example, as described in U.S. patent application Ser. No. 16/852,118, filed Apr. 17, 2020, and entitled “Systems and Methods for Acoustic Limits of Thermal Control System in an Information Handling System,” which is incorporated by reference herein in its entirety.

In some embodiments, thermal control system 114 may include a program of instructions (e.g., software, firmware) configured to, when executed by a processor or controller integral to management controller 112, carry out the functionality of thermal control system 114.

Temperature sensor 118 may comprise any system, device, or apparatus (e.g., a thermometer, thermistor, etc.) configured to communicate a signal to thermal control system 114 indicative of a temperature within information handling system 102.

Altitude sensor 120 may comprise any system, device, or apparatus configured to communicate a signal to thermal control system 114 indicative of an altitude at which information handling system 102 is located. For example, in some embodiments, altitude sensor 120 may include a barometric pressure sensor. As another example, in other embodiments, altitude sensor 120 may include a Global Positioning System (GPS) receiver or other satellite-based positioning system receiver. In yet other embodiments, altitude sensor 120 may be implemented in effect by using components of information handling system 102 indicative of location, such as location determination based on the source of a wireless cellular signal received by information handling system 102, based on the source of a Wireless Fidelity (Wi-Fi) signal received by information handling system 102, and/or other location-based mechanism.

In addition to processor 103, memory 104, air mover 108, management controller 112, temperature sensor 118, and altitude sensor 120, information handling system 102 may include one or more other information handling resources. In addition, for the sake of clarity and exposition of the present disclosure, FIG. 1 depicts only one air mover 108 and temperature sensor 118. In embodiments of the present disclosure, information handling system 102 may include any number of air movers 108 and temperature sensors 118.

FIG. 2 illustrates a flow chart of an example method 200 for air mover speed optimization based on altitude, in accordance with embodiments of the present disclosure. According to one embodiment, method 200 may begin at step 202. As noted above, teachings of the present disclosure may be implemented in a variety of configurations of information handling system 102 and/or thermal control system 114. As such, the preferred initialization point for method 200 and the order of the steps comprising method 200 may depend on the implementation chosen.

At step 202, thermal control system 114 may receive an indication of an altitude of information handling system 102. In some embodiments, such indication may be received from altitude sensor 120. However, in embodiments in which altitude sensor 120 is not present or is inoperative, such indication may be made based on a manual setting of altitude provided by a user or administrator of information handling system 102.

At step 204, thermal control system 114 may determine, based on the altitude, an altitude-based adjustment factor to be applied to a temperature-based control loop for determining air mover speed. For example, in some embodiments, the altitude-based adjustment factor may be ascertained by determining a maximum air mover speed based on altitude (e.g., applying higher maximum air mover speeds at higher altitudes and lower maximum air mover speeds at lower altitudes), and the temperature-based control loop may be configured to determine a percentage of the maximum speed to operate air mover 108 based on temperature. As a specific example, at a particular temperature, the temperature-based control loop may determine that air mover 108 should operate at a percentage X of its maximum speed. Further, an altitude-based control loop of air mover 108 may determine that a maximum speed for air mover 108 at low altitudes is V_{LO} and the maximum speed for air mover 108 at high altitudes is V_{HI}. Thus, in this particular example, thermal control system 114 may cause air mover 108 to operate at speed X·V_{LO} at lower altitudes and to operate at speed X·V_{HI} at higher altitudes.

As another example, in some embodiments, the temperature-based control loop may determine a raw speed at which to operate air mover 108 based on temperature and the altitude-based control loop may determine a multiplicative factor to be applied to the raw speed based on altitude. As a specific example, at a particular temperature, the temperature-based control loop may determine that air mover 108 should operate at a speed V. Further, an altitude-based control loop of air mover 108 may determine a multiplicative factor of K_{LO} at low altitudes and a multiplicative factor of K_{HI} at high altitudes. Thus, in this particular example, thermal control system 114 may cause air mover 108 to operate at speed K_{LO}·V at lower altitudes and to operate at speed K_{LO}·V at higher altitudes.

For the purposes of clarity and exposition, the foregoing examples contemplate the use of binary values for the altitude-based adjustment factor (e.g., the altitude-based adjustment factor having a first value for altitudes below a threshold altitude and a second value larger than the first value for altitudes below a threshold altitude). However, in some embodiments, the altitude-based adjustment factor may have more than two possible values, and may include a range of altitude-based values set forth in a look-up table, determined in accordance with an algebraic equation (e.g., with altitude as the independent variable and the altitude-based adjustment factor as the dependent variable), and determined in any other suitable manner.

At step 206, thermal control system 114 may apply the altitude-based adjustment factor to the air mover control value determined by the temperature-based control loop and generate a control signal to motor 110 to control air mover speed based on temperature and altitude. After completion of step 206, method 200 may proceed again to step 202.

Although FIG. 2 discloses a particular number of steps to be taken with respect to method 200, method 200 may be executed with greater or lesser steps than those depicted in FIG. 2. In addition, although FIG. 2 discloses a certain order of steps to be taken with respect to method 200, the steps comprising method 200 may be completed in any suitable order.

Method 200 may be implemented using information handling system 102, thermal control system 114, or any other system operable to implement method 200. In certain embodiments, method 200 may be implemented partially or fully in software and/or firmware embodied in computer-readable media.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

To aid the Patent Office and any readers of any patent issued on this application in interpreting the claims appended hereto, applicants wish to note that they do not intend any of the appended claims or claim elements to invoke 35 U.S.C. § 112(f) unless the words “means for” or “step for” are explicitly used in the particular claim.

What is claimed is:

1. An information handling system comprising:
an information handling resource;
an air mover configured to drive air to cool the information handling resource; and
a thermal control system for controlling the air mover and configured to, based on an altitude of the information handling system, regulate an air mover speed of the air mover.

2. The information handling system of claim 1, further comprising an altitude sensor configured to generate a signal indicative of the altitude.

3. The information handling system of claim 2, wherein the altitude sensor comprises a barometric pressure sensor.

4. The information handling system of claim 2, wherein the altitude sensor is a satellite-based positioning system receiver.

5. The information handling system of claim 1, wherein:
the information handling system further comprises a temperature sensor; and
the thermal control system is further configured to, based on a temperature associated with the information handling system, regulate the air mover speed of the air mover.

6. The information handling system of claim 5, wherein the thermal control system is configured to:
determine an altitude-based adjustment factor for the air mover speed based on the altitude;
determine a temperature-based control value for the air mover speed based on the temperature; and
generate a control signal to the air mover to control the air mover speed.

7. A method comprising:
obtaining an indication of an altitude of an information handling system; and
based on an altitude of the information handling system, regulating an air mover speed of an air mover of the information handling system.

8. The method of claim 7, wherein the indication of the altitude is a signal indicative of the altitude generated by an altitude sensor.

9. The method of claim 8, wherein the altitude sensor comprises a barometric pressure sensor.

10. The method of claim 8, wherein the altitude sensor is a satellite-based positioning system receiver.

11. The method of claim 7, further comprising based on a temperature associated with the information handling system, regulating the air mover speed of the air mover.

12. The method of claim 11, wherein regulating the air mover speed of the air mover comprises:
determining an altitude-based adjustment factor for the air mover speed based on the altitude;
determining a temperature-based control value for the air mover speed based on the temperature; and
generating a control signal to the air mover to control the air mover speed.

13. An article of manufacture comprising:
a non-transitory computer-readable medium; and
computer-executable instructions carried on the computer-readable medium, the instructions readable by a processing device, the instructions, when read and executed, for causing the processing device to:
obtain an indication of an altitude of an information handling system; and
based on an altitude of the information handling system, regulate an air mover speed of an air mover of the information handling system.

14. The article of claim 13, wherein the indication of the altitude is a signal indicative of the altitude generated by an altitude sensor.

15. The article of claim 14, wherein the altitude sensor comprises a barometric pressure sensor.

16. The article of claim 14, wherein the altitude sensor is a satellite-based positioning system receiver.

17. The article of claim 13, the instructions for further causing the processing device to regulate the air mover speed of the air mover based on a temperature associated with the information handling system.

18. The article of claim 17, wherein regulating the air mover speed of the air mover comprises:
determining an altitude-based adjustment factor for the air mover speed based on the altitude;
determining a temperature-based control value for the air mover speed based on the temperature; and
generating a control signal to the air mover to control the air mover speed.
